(19) United States
(12) Patent Application Publication
(10) Pub. No.: US 2026/0020497 A1
(43) Pub. Date: Jan. 15, 2026

(54) THERMOELECTRIC GENERATOR APPARATUSES AND SYSTEMS

(71) Applicant: National Thermovoltaics Inc., Nisku (CA)

(72) Inventors: Robert Daniel, Alpharetta, GA (US); Kelly James ADAMS, Nisku, AB (CA); Nicholas Campbell, Nisku, AB (CA)

(21) Appl. No.: 18/993,933

(22) PCT Filed: Jul. 10, 2023
(86) PCT No.: PCT/CA2023/050924

§ 371 Date: Jan. 13, 2025

Related U.S. Application Data
(60) Provisional application No. 63/388,882, filed on Jul. 13, 2022.

(51) Int. Cl. H10N 10/17

(52) U.S. Cl. CPC H10N 10/17

(57) ABSTRACT

A thermoelectric generator (TEG) apparatus includes a plurality of hot-side heat exchange plates for receiving a heating thermal fluid: and a plurality of cold-side heat exchange plates for receiving a coolant thermal fluid. The cold-side heat exchange plates and hot-side heat exchange plates are interleaved such that each hot-side heat exchange plate is positioned intermediate a respective pair of cold-side heat exchange plates. The apparatus also includes. for each adjacent hot-side heat exchange plate and cold-side heat exchange plate. a respective TEG clement layer interposed between the hot-side heat exchange plate and the cold-side heat exchange plate. A TEG system may include the TEG apparatus and a heating thermal fluid system and a coolant thermal fluid system.

### RELATED APPLICATION

This application claims priority to U.S. Provisional Patent Application No. 63/388,882, filed Jul. 13, 2022, the entire contents of which are incorporated by reference.

### FIELD OF THE DISCLOSURE

The present application relates to systems for generating electrical power with solid state thermoelectric generators, which may also be known as thermovoltaic generators.

### BACKGROUND

A thermoelectric generator (TEG) may be used to convert heat energy into electric energy. A typical solid state TEG module may include a thermoelectric circuit comprising one or more thermoelectric materials and electrical conductor interconnects arranged to generate electrical power in response to a temperature differential applied across the thermoelectric material(s). The TEG module may have a “hot side” and a “cold side.” A TEG module may further include a substrate layer (e.g. ceramic) covering the conductor interconnects on either side of the module.

Thermoelectric generators are commonly used as a power source for spacecraft by using heat generated from decaying radioisotopes and for operating gas pipelines by using heat generated from gas combustion. Thermoelectric generators maybe reliable and low-maintenance or maintenance free because they have no moving parts and can function in environments that would limit the use of other power sources, such as solar. Commercial use of thermoelectric generator systems generally includes applying heat directly to a thermoelectric generator by burning fuel in a controlled fashion and passively rejecting the heat directly to the atmosphere. However, where there is a sufficient available source of waste heat, direct application and rejection of heat may not be practical for large-scale thermoelectric power generation.

### SUMMARY

According to an aspect, there is provided a thermoelectric generator (TEG) apparatus comprising: a plurality of hot-side heat exchange plates for receiving a heating thermal fluid; a plurality of cold-side heat exchange plates for receiving a coolant thermal fluid, the cold-side heat exchange plates and hot-side heat exchange plates being interleaved such that each hot-side heat exchange plate is positioned intermediate a respective pair of cold-side heat exchange plates; and for each adjacent hot-side heat exchange plate and cold-side heat exchange plate, a respective TEG element layer interposed between the hot-side heat exchange plate and the cold-side heat exchange plate.

In some embodiments, the TEG layer comprises a plurality of TEG elements, each TEG module comprising a hot side and a cold side and configured for thermoelectric generation of electricity when a heat gradient is applied across the TEG element, wherein the hot sides of the TEG elements are positioned adjacent the hot-side heat exchange plates, and the cold sides of the TEG elements are positioned adjacent the cold-side heat exchange plates.

In some embodiments, the TEG apparatus further comprises, for each TEG element layer, an insulating material at least partially filling gaps between the TEG elements of the TEG element layer.

In some embodiments, the hot-side heat exchange plates form a condenser for receiving the heating thermal fluid as a first vapor and condensing the thermal fluid to a first liquid; and the cold-side heat exchange plates form an evaporator for receiving the coolant thermal fluid as a second liquid and evaporating the thermal fluid to a second vapor.

In some embodiments, the hot-side heat exchange plates each comprise a respective heating thermal fluid inlet and heating thermal fluid outlet, the cold-side heat exchange plates each comprise a respective coolant thermal fluid inlet and coolant thermal fluid outlet.

In some embodiments, the apparatus further comprises: a heating thermal fluid supply line coupled in parallel to heating thermal fluid inlets of the hot-side heat exchange plates; a heating thermal fluid return line coupled in parallel to the heating thermal fluid outlets the hot-side heat exchange plates; a coolant thermal fluid supply line coupled in parallel to coolant thermal fluid inlets of the cold-side heat exchange plates; and a coolant thermal fluid return line coupled in parallel to coolant thermal fluid outlets of the cold-side heat exchange plates.

In some embodiments, the TEG apparatus further comprises a pressure equalization line connected between the heating thermal fluid supply line and the heating thermal fluid return line.

In some embodiments, the TEG apparatus further comprises first and second end plates, wherein the hot-side heat exchange plates, the cold-side heat exchange plates, and the TEG element layers are secured between the first and second end plates.

In some embodiments, the TEG apparatus further comprises one or more biasing elements to apply a compressive force to the first and second end plates, hot-side heat exchange plates, the cold-side heat exchange plates, and the TEG element layers.

According to another aspect, there is provided a thermoelectric generator (TEG) system, comprising: one or more TEG apparatuses, each comprising: a respective plurality of hot-side heat exchange plates for receiving a heating thermal fluid; a respective plurality of cold-side heat exchange plates for receiving a coolant thermal fluid, the cold-side heat exchange plates and hot-side heat exchange plates being interleaved such that each hot-side heat exchange plate is positioned intermediate a respective pair of cold-side heat exchange plates; and for each adjacent hot-side heat exchange plate and cold-side heat exchange plate, a respective TEG element layer interposed between the hot-side heat exchange plate and the cold-side heat exchange plate; a heating thermal fluid system, comprising a heating thermal fluid supply line and a heating thermal fluid return line, each coupled to the hot-side heat exchange plates of the one or more TEG apparatuses; and a coolant thermal fluid system, comprising a coolant thermal fluid supply line and a coolant thermal fluid return line, each coupled to the cold-side heat exchange plates of the one or more TEG apparatuses.

In some embodiments, the TEG system further comprises a pressure equalization line connected between the heating thermal fluid supply line and the heating thermal fluid return line.

In some embodiments, the hot-side heat exchange plates each comprise a respective heating thermal fluid inlet and heating thermal fluid outlet, the cold-side heat exchange plates each comprise a respective coolant thermal fluid inlet and coolant thermal fluid outlet, and the heating thermal fluid supply line is coupled in parallel to heating thermal fluid inlets of the hot-side heat exchange plates; the heating thermal fluid return line is coupled in parallel to the heating thermal fluid outlets the hot-side heat exchange plates; the coolant thermal fluid supply line is coupled in parallel to coolant thermal fluid inlets of the cold-side heat exchange plates; and the coolant thermal fluid return line is coupled in parallel to coolant thermal fluid outlets of the cold-side heat exchange plates.

In some embodiments, the TEG system further comprises: a first closed two-phase heat transfer loop arranged to deliver heat from a heat source to the plurality of hot-side heat exchange plates, first closed two-phase heat transfer loop comprising the heating thermal fluid supply line and the heating thermal fluid return line; and a second closed two-phase heat transfer loop arranged to transfer heat away from the plurality of cold-side heat exchange plates, the second closed two-phase heat transfer loop comprising the coolant thermal fluid supply line and the coolant thermal fluid return line.

In some embodiments: the first closed two-phase heat transfer loop comprises a first thermosyphon for circulating the heating thermal fluid; and/or the second closed two-phase heat transfer loop comprises a second thermosyphon for circulating the coolant thermal fluid.

In some embodiments, the TEG system further comprises: one or more heat exchangers arranged to transfer heat from a heat source to the heating thermal fluid; and one or more other heat exchangers arranged to remove heat from the coolant thermal fluid.

In some embodiments, the one or more TEG apparatuses of the TEG system comprise a plurality of TEG apparatuses, and each TEG apparatus may be as described herein.

According to another aspect, there is provided a method for generating electrical energy using the TEG apparatus as described herein, the method comprising: applying a heat gradient across the TEG layers comprising: flowing the heating thermal fluid through the plurality of hot-side heat exchange plates of the TEG apparatus; and flowing the coolant thermal fluid through the plurality of cold-side heat exchange plates of the TEG apparatus.

In some embodiments: flowing the heating thermal fluid comprises circulating the heating thermal fluid in a first closed two-phase heat transfer loop comprising the heating thermal fluid supply line and a heating thermal fluid return line; and flowing the coolant thermal fluid comprises circulating the coolant thermal fluid in a second closed two-phase heat transfer loop comprising the coolant thermal fluid supply line and a coolant thermal fluid return line.

In some embodiments, the first closed two-phase heat transfer loop comprises a first thermosyphon for circulating the heating thermal fluid; and/or the second closed two-phase heat transfer loop comprises a second thermosyphon for circulating the coolant thermal fluid.

Other aspects and features of the present disclosure will become apparent to those ordinarily skilled in the art, upon review of the following description of the specific embodiments of the disclosure.

### BRIEF DESCRIPTION OF THE DRAWINGS

The present disclosure will be better understood having regard to the drawings in which:

FIG. 1 is a schematic diagram of an example two closed, two-phase loop TEG system according to some embodiments;

FIG. 2 is a schematic diagram of another example two closed, two-phase loop TEG system according to some embodiments;

FIG. 3 is a schematic diagram of another example two closed, two-phase loop TEG system according to some embodiments;

FIG. 4 is a schematic diagram of an example two closed, two-phase flow loop TEG system according to some embodiments;

FIG. 5 is a side cross-sectional view of an example TEG apparatus according to some embodiments;

FIG. 6 is a front view of an example plate that may be used as a hot plate or cold plate according to some embodiments;

FIGS. 7 and 8 are top and side cross-sectional views, respectively, of the plate 600 of FIG. 6;

FIG. 9 is a perspective view of another example TEG apparatus according to some embodiments;

FIG. 10A is a schematic diagram illustrating an example TEG system comprising a plurality of TEG apparatuses connected in parallel to hot-side thermal fluid lines and cold-side thermal fluid lines;

FIG. 10B is a schematic diagram illustrating fluid connections to one of the TEG apparatuses of the system of FIG. 10A;

FIG. 11 is perspective diagram view of the system of FIG. 10A, including six TEG apparatuses;

FIG. 12 is a top view diagram of an example the TEG system of FIGS. 10 and 11;

FIG. 13 is a front view of one TEG apparatus of FIG. 12 illustrating fluid connections thereto;

FIG. 14 a top view diagram of another example TEG system including TEG apparatuses and hot-side and cold-side fluid systems;

FIG. 15 is a front view of the two TEG apparatuses of FIG. 14 and illustrating fluid connections thereto;

FIG. 16 is a flow chart of a method according to some embodiments.

### DETAILED DESCRIPTION

The following discussion is presented to enable a person skilled in the art to make and use the claimed subject matter. Various modifications will be readily apparent to those skilled in the art, and the general principles described herein may be applied to embodiments and applications other than those detailed below without departing from the spirit and scope of the disclosure. The embodiments described herein are not intended to be limited to the particular embodiments shown, but are to be accorded the widest scope consistent with the principles and features disclosed herein.

The present disclosure relates generally to thermoelectric generator (TEG) apparatuses and systems including TEG apparatuses. The disclosure also relates to transfer of heat to and from one or more TEG apparatuses for the purpose of generating electricity. The TEG systems may employ two closed, two-phase thermal fluid loops, although embodiments are not limited to such configurations. The systems described herein provide advantages such as: providing flexibility for different applications; preventing possibly contaminated and corrosive waste heat sources from impacting more than the associated heat exchanger; and/or improving the economics of applying thermoelectric generators to large scale power production. In addition, as the efficiency of thermoelectric generators improve, the economics of using them for large scale power production becomes more favorable.

According to an aspect, a TEG system may comprise one or more TEG apparatuses and two closed thermal fluid loops. The two closed loops may include a heating loop, which delivers heat to the hot side of one or more TEG apparatus(s), and a cooling loop which transfers heat away from the cold of the TEG apparatus(s). The heating and cooling loops may be two-phase closed loops.

A two-phase closed heating loop may convey heat from a heat source by: vaporizing a liquid in the heating loop by means of heat from the heat source to generate a vapor; and transmitting that heat by condensing the vapor on a “hot side” side of TEG apparatus(s). A two-phase closed cooling loop may pull heat away from the TEG apparatus(s) by vaporizing a liquid in the cooling loop at a “cold side” of the TEG apparatus(s). The vapor in the cooling loop then flows to a condenser away from the TEG apparatus(s) where the vapor is condensed back into a liquid state, such that heat is released into the environment around the condenser. The condenser may, for example, be air-cooled or water-cooled depending on the availability of cooling water. The heating and cooling loops may thereby provide a temperature differential across the TEG apparatus(s) that translates into the generation of power. In addition, the thermal fluid loops may allow the consolidation of heat transfer into three sections: heat transfer from an external source, heat transfer across the TEG apparatus(s), and heat transfer to an external source by providing the ability to effectively transmit that heat between these sections.

The term “hot side” as used herein may refer to a side of a TEG element to which heat is delivered for generating electrical energy. The term “hot side” may also refer functionally to elements arranged for delivering heat to the TEG element. Heat exchange plates arranged for heat delivery to the “hot side” of one or more TEG elements may be referred to as “hot plates” herein.

The term “cold side” as used herein may refer to the side of a TEG element from which heat is removed (i.e. the cooled side). The term “cold side” may also refer functionally to elements arranged for removing heat from the TEG element. Heat exchange plates arranged for cooling the “cold side” of one or more TEG elements may be referred to as “cold plates” herein.

A hot-side closed loop (i.e., “heating loop”) may use heat supplied from an external source such as waste heat, geothermal heat, or combusted fuel to vaporize a liquid in a heat exchanger; transmit the energy to the hot side of the TEG elements as a condensing vapor; and recirculate the liquid back to the heat source. A cold-side closed loop (i.e., “cooling loop”) may use heat that passes through the TEG elements to vaporize a liquid on the cold side of the TEG elements; transmit the energy to a condenser; and recirculate the liquid back to the cold side of the TEG elements. The TEG elements may be sandwiched between hot plates and cold plates to provide a temperature differential that induces the TEG elements to generate power. The term “TEG element” as used herein may refer to a TEG module or any other device including a thermoelectric material and configured to generate electrical energy in response to a thermal differential applied across the thermal material. For example, TEG modules may be in the form of high efficiency TEG cartridges, although embodiments are not limited to a particular type of TEG module.

The use of two-phase flow may provide consistency of temperature at the interface of the TEG elements by relying on the latent heat of vaporization to help maintain temperature uniformity. In addition, using two-phase flow may reduce the recirculation flow rate in each loop by allowing more enthalpy to be stored in the phase change of a unit mass of recirculating fluid as compared to what can be stored in the same mass of single-phase recirculating fluid. The systems and apparatuses described herein may also allow a reduced overall volume of the loops' fluid inventories compared to recirculating single-phase liquid systems. Using closed loops on both sides of the TEGs prevents the loss of the recirculating fluid.

The motive force for recirculating two-phase flow can be provided by any suitable means. For example, the liquid motive force may be provided by a thermosyphon and/or or a pump. Either loop or both loops may include a pump or thermosyphon. A thermosyphon recirculates fluid due to natural convention. The term “natural convection,” as used herein, means fluid recirculates without mechanical force as provided by a pump for liquid or a compressor for vapor. According to certain embodiments, the buoyancy of the vapor and liquid height difference between where the vapor is condensed and where it is vaporized may provide the driving force for recirculating a fluid in a thermosyphon loop. A thermosyphon may eliminate the need for a pump and thereby reduce power required by the system. The utility of a thermosyphon may depend on the available height for a particular application and other factors.

Instrumentation and controls may be used to regulate the flow of heat into and out of the loops; to monitor the temperature and/or pressure of the loops; and to control the conditions of the loops to maximize power generation, prevent over-pressurizing the loops, and over-heating the TEGs. Chemicals may be added to the fluid in either or both loops to prevent against corrosion and/or enhance heat transfer.

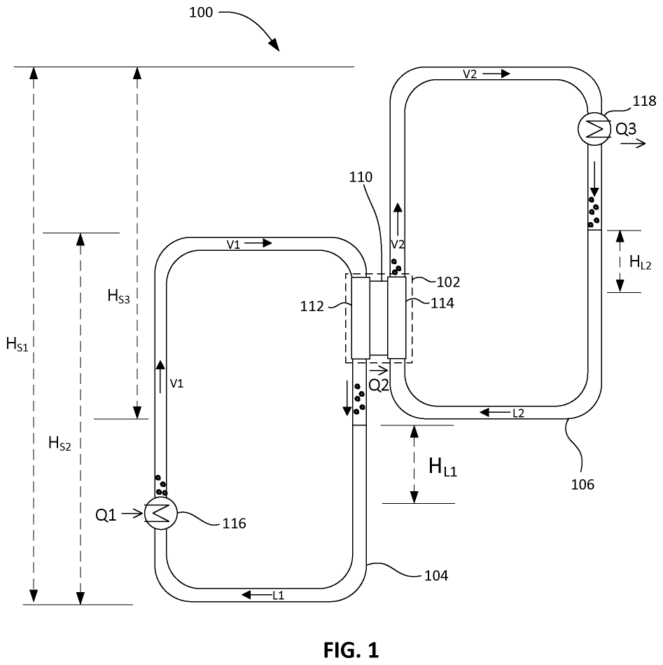

FIG. 1 is a schematic diagram of an example TEG system 100 according to some embodiments. The system 100 includes a TEG apparatus 102, a heating loop 104 and a cooling loop 106. The heating loop 104 is a two-phase closed loop containing a “hot-side” thermal fluid, and the heating loop 104 delivers heat Q1 from a heat source 108 (not shown) to one or more hot plate 112 of one or more TEG apparatuses 102. The heat source may, for example, be from combustion exhaust gases, blowdown steam, geothermal heat, and/or the final stage of a Rankin Cycle. Embodiments are not limited to a specific type of heat source. The cooling loop 106 is another two-phase closed loop containing a “cold-side” thermal fluid, that the cooling loop 106 transfers heat away from one or more cold plates 114 at a cold-side of the one or more TEG apparatuses. FIG. 1 illustrates how two fluid phases of the hot and cold-side thermal fluids and heat may flow through the loops (104, 106) when thermosyphons are employed for both loops. That is, the heating loop 104 and the cooling 106, in this example, each function as thermosyphons for flowing the corresponding fluid through the loops 104 and 106.

The hot-side thermal fluid circulating in the heating loop 104 may, for example, comprise water, ethylene glycol, or diethylbenzene. The cold-side thermal fluid circulating in the cooling loop 106 may, for example, comprise ammonia, R134a, or R600a. The cold-side thermal fluid circulating in the cooling loop 106 may be referred to as the “refrigerant” or “coolant” herein. Embodiments are not limited to any particular thermal fluid(s) for use in the heating loop or cooling loop. The hot-side thermal fluid may have a boiling point that is higher than the boiling point of the cold-side thermal fluid.

In FIG. 1, the overall height of the combination of loops (104, 106) is labeled H_{S1}, the height of the heating loop 104 is labeled H_{S2}, the height of the cooling loop 106 is labeled H_{S3}. The height of each thermosyphon loop (heating and cooling loops 104 and 106) shown in FIG. 1 may depend on hydraulics and associated equipment, such as heat exchangers and receivers. H_{L1} is the elevation difference between the two-phase interface and that within the heat exchanger in the heating loop. H_{L2} is the elevation difference between the two-phase interface and within the cold plates in the TEG apparatus in the cold-side loop. The heights H_{L1} and H_{L2} are the liquid heads that in turn provide the motive force for the liquids in the system. The lower the hydraulic loses throughout each loop (104, 106) the smaller heights H_{L1} and H_{L2} can become; and consequently H_{S1}, H_{S2}, and H_{S3}.

At a hot-side heat exchanger 116, heat is transferred from the heat source to the hot-side fluid as latent heat absorbed by liquid (L1), thereby converting the liquid to vapor (V1). This heat transfer is illustrated by arrow Q1 in FIG. 1. The hot-side vapor (V1) in the heating loop 104 flows to the hot side of the TEG apparatus 102. The heating loop may flow through one or more hot plates, where the vapor (V1) condenses and transfers heat through the TEG elements 110 to the cold side 114 of the TEG apparatus 102. This heat transfer across the TEG apparatus 102 is illustrated as arrow Q2. Some heat across the TEG apparatus 102 is converted to electrical energy. The cooling loop 106 extends through the cold side 114 of the TEG apparatus 102. The heat energy through the TEG apparatus 102 that is not converted to electrical energy is absorbed by cold-side liquid (L2), within the cold side of the TEG apparatus 102, by the cold-side liquid (L2) converting to vapor (V2). The vapor (V2) travels in the cooling loop 106 and is ultimately transferred to the environment at a cold-side heat exchanger 118 as the cold-side vapor (V2) condenses. This transfer to the environment is illustrated by arrow Q3.

The TEG apparatus 102 comprises one or more TEG elements 110 sandwiched between one or more hot plates 112 and cold plates 114 to provide a temperature differential across the TEG element(s) 110 that induces the TEG element(s) 110 to generate electrical power.

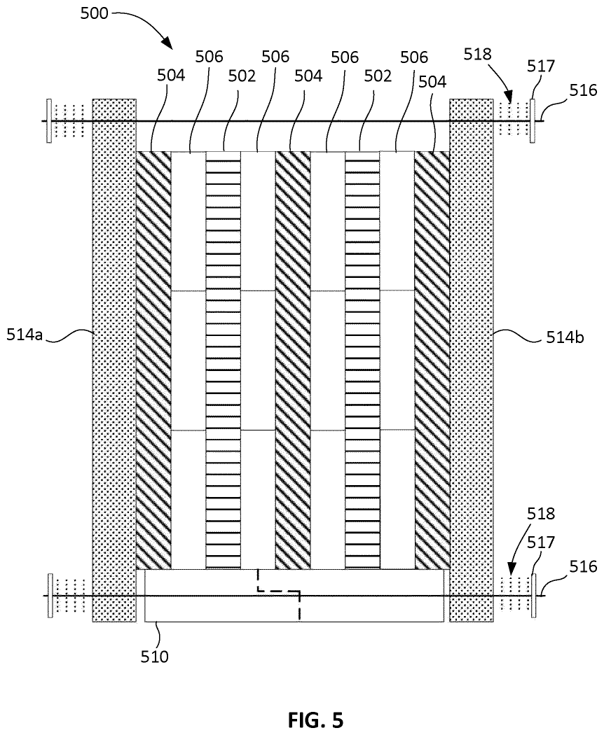

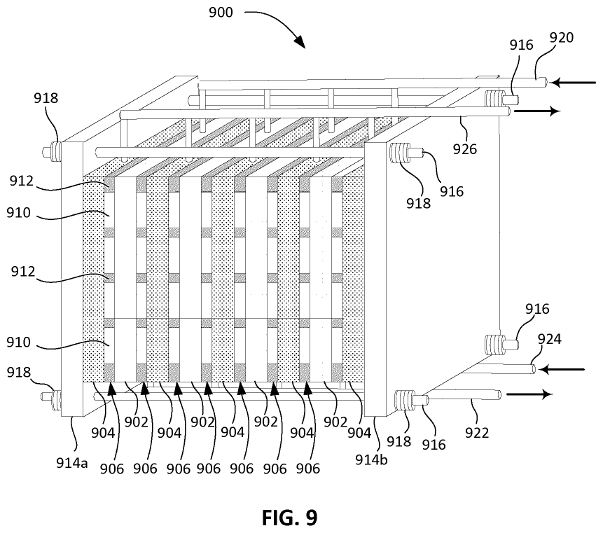

The electrical power generated by the TEG element(s) 110 may increase with increasing temperature differential. In some embodiments, the TEG apparatus 102 may comprise a plurality of TEG elements 110 stacked between alternating hot plates and cold plates, with each adjacent pair of hot and cold plates (212,214) having one or more TEG elements 110 positioned therebetween. That is, the hot plates 112 and cold plates 114 may be interleaved or arranged in an alternating fashion, with each hot plate positioned intermediate a pair of cold plates. TEG elements may be interposed between adjacent pairs of hot and cold plates. See, for example, the TEG apparatuses 500 and 900 shown in FIGS. 5 and 9 and described below.

The hot plate(s) of the hot side 112 in TEG apparatuses 102, or in other embodiments described herein, may function as condensers. The cold plate(s) of the cold side 114 may function as boilers (or evaporators). Each hot plate and cold plate may comprise tubing or channels embedded in one or more plate bodies (e.g. aluminum plate body). The tubing or channels may carry the corresponding hot or cold-side fluid through plate bodies for the corresponding heat transfer.

The hot-side heat exchanger 116 or “boiler” may be a welded plate type, tube and shell type, or a tube and fin type and is to be referred to as the boiler herein. Heat from a source may be delivered to the heat exchanger 116 to boil the hot-side thermal fluid therein. The heat source may be waste heat from other equipment, for example.

The cold-side heat exchanger 118 may be referred to as a condenser herein. The condenser 118 may, for example, be a fan-cooled tube and fin type, a water-cooled shell and tube type, water-cooled braised or welded plate and frame type, or a passive air-cooled tube and fin type, or channels may be used in place of tubes in the before mentioned condensers. The type of boiler and condenser to be used for a particular application may depend on the heat source, ambient conditions, availability of cooling water, and space constraints. Where a fan-cooled condenser is used, the fan speed may be adjusted to optimize the fan's speed and consequential energy consumption with the increase power output of the TEG apparatus associated with a lower cold-side operating temperature.

The use of two separate two-phase flow closed loops (i.e., the heating loop and cooling loop shown in FIG. 1) may provide various advantages over pumped single-phase liquid TEG systems. For example, vaporizing the fluid in a loop may allow transfer of heat with much lower mass flow rates than would be required for equivalent heat transfer using a pumped single-phase liquid. The latent heat of vaporization of the fluid in a loop may allow a large amount of energy to be transferred within the fluid without a change in temperature of the fluid. Additional heat energy may result in increased temperature after the initial vaporization. Additionally, the tubing or pipes forming the loops may have a smaller inner diameter with slower fluid flow rates than pumped single-phase systems. The system may also have a reduced overall volume of fluid inventories compared to pumped single-phase systems.

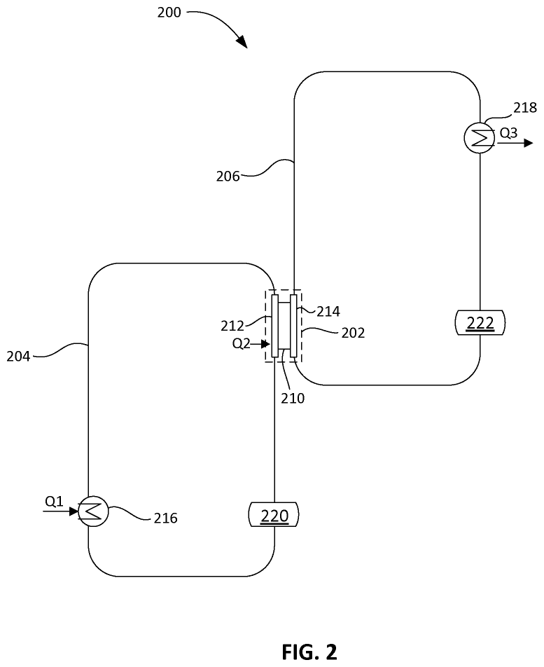

FIG. 2 is a schematic diagram of another TEG system 200 according to some embodiments. The system 200 of FIG. 2 is similar to the system 100 of FIG. 1 in that the system 200 includes a TEG apparatus 202, a heating loop 204 and a cooling loop 206. The system 200 of FIG. 2 also utilizes thermosyphons to circulate the hot-side and cold-side thermal fluids through the heating loop 204 and the cooling loop 206 respectively. A hot-side heat exchanger 216 transfers heat from a heat source (not shown) into the heating loop 204. A cold-side heat exchanger 218 transfers heat from the cooling loop 206 to the environment.

In this example, the TEG system 200 further includes a hot-side thermal fluid receiver 220 in the heating loop 204 (where the hot-side thermal fluid is in liquid state) and a cold-side thermal fluid receiver 222 in the cooling loop 206 (where the cold-side thermal fluid is in liquid state). Receivers 220 and 222 may be used for hydraulic buffering and may comprise a fluid reservoir for isolating the liquid while the system is pumped down.

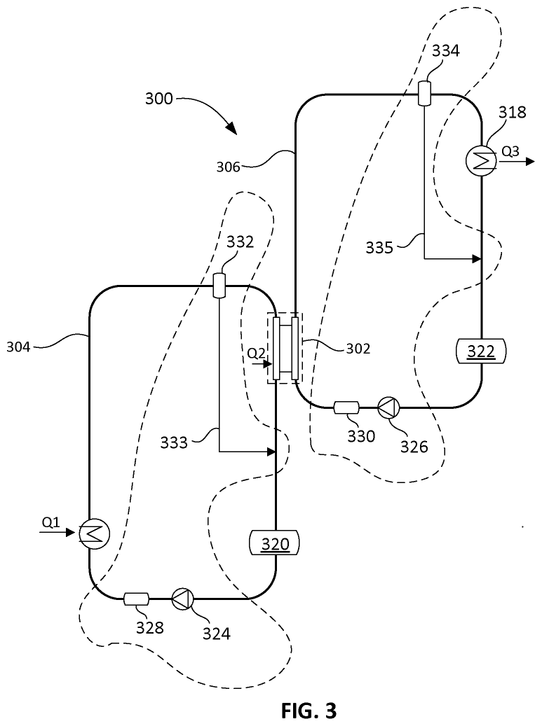

FIG. 3 is a schematic diagram of another two two-phase flow closed loop TEG system 300 according to some embodiments. Like the embodiments of FIGS. 1 and 2, the TEG system includes a TEG apparatus 302, a heating loop 304 and a cooling loop 306 in similar arrangement. The TEG apparatus 302 may be similar to the TEG apparatuses 102 and 202 of FIGS. 1 and 2. This embodiment also includes thermal fluid receivers 320 and 322 similar the receivers 220 and 222 of FIG. 2.

In this embodiment, however, the system 300 further comprises pumps hot-side pump 324 and cold-side pump 326 to mechanically recirculate fluid in the corresponding loops (304,306). Pumps may be used instead of, or in addition to, thermosyphons (i.e. natural convection) in one or both loops (304,306) as means of recirculating the fluids contained in the loops. The pumps 324 and 326 in this embodiment may be hermetically sealed pumps. In other embodiments, one of the heating and cooling loops may comprise a thermosyphon and the other heating or cooling loop may comprise a pump for recirculating.

The TEG system 300 further optionally includes a hot-side fluid treatment apparatus 328 in the heating loop 304 and a cold-side fluid treatment apparatus 330 in the cooling loop 306. The treatment apparatuses (328,330) may remove and/or treat contaminants in the thermal fluids through possible filtration and/or chemical reactions. The treatment apparatuses may include, for example, a filter such as an inline filter that is commonly installed in air conditioning systems to remove and treat contaminants in the refrigerant.

The TEG system 300 further optionally includes a hot-side separator 332 in the heating loop 304 and a cold-side separator 334 in the cooling loop 306. The separators 332 and 334 may be used for separating the phases of the corresponding thermal fluid. For example, one or both separators 332 and 334 may be a stand-pipe or cyclone type separator that separates two phase pumped fluid. The hot-side separator 332 may provide that vapor is primarily delivered to the hot-side of the TEG apparatus 302. The cold-side separator 334 may provide that vapor is primarily delivered to the condenser 318. Bypass fluid lines 333 and 335 exiting the bottom of each separator 332 and 334 may allow liquid to bypass the downstream hot plates or condenser 318 respectively.

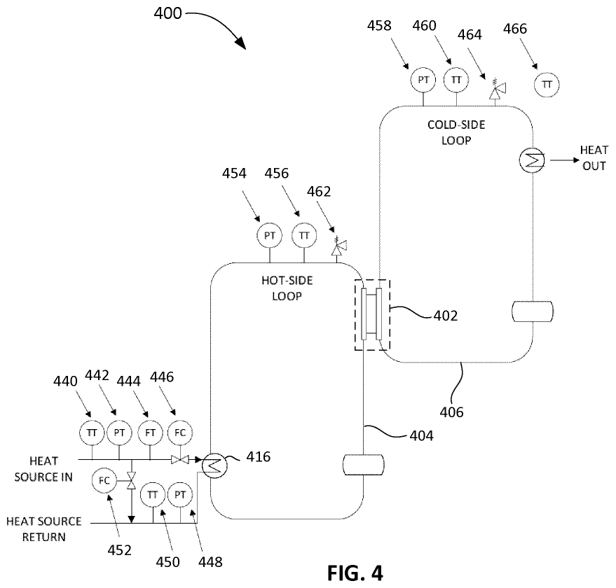

FIG. 4 is a schematic diagram of another two two-phase flow loop TEG system 400 according to some embodiments. The TEG system 400 again includes a TEG apparatus 402, heating loop 404 and cooling loop 406 (similar to FIGS. 1 to 3). The loops (404,406) may use a thermosyphon or pumps to recirculate fluid in either or both loops. The system 400 also includes example optional controls for the loops (404,406). These controls include, but are not limited to: first temperature transmitter 440; first pressure transmitter 442; flow transmitter 444; and first control valve 446, each coupled to a heat-source-in line to hot-side heat exchanger 416. The controls further a second pressure transmitter 448 and a second temperature transmitter 450 coupled inline with a heat-source-return line from the hot-side heat exchanger 416, and a bypass flow control 452 between the heat source in line and the heat source return line.

The first and second temperature transmitters 440 and 450, the first and second pressure transmitters 442 and 448 and the flow transmitter 444 may be used to calculate the heat input into the TEG system 400, to monitor system performance, and minimize the possibility of over pressurizing the heating loop 404 and overheating the TEG elements of the TEG apparatus. The first flow control valve 446 and bypass flow control valve 452 may be used to regulate heat input into the heating loop 404.

The bypass flow control valve 452 in this example is arranged to allow flow to bypass heat flow into the system 400. The bypass flow control valve 452 may be included, for example, if the heating source must not exceed a certain back pressure, as may be the case for exhaust gases used as a heat source.

The TEG system 400 further optionally includes third and forth pressure transmitters 454 and 458 and third and fourth temperature transmitters 456 and 460. The third pressure transmitter 454 and third temperature transmitter 456 are coupled to the heating loop 404, and the fourth pressure transmitter 458 and fourth temperature transmitter 460 are coupled to the cooling loop 406. The third and forth pressure transmitters 454 and 458 and third and fourth temperature transmitters 456 and 460 may be used to monitor the performance of the loops (404,406) to ensure that measured pressure sufficiently matches the expected saturation pressure for the associated measured temperature and are used to protect against overpressure and overtemperature.

The TEG system 400 further optionally includes a first pressure safety valve 462 coupled to the heating loop 404 and a second pressure safety valve 464 coupled to the cooling loop 406. The pressure safety valves 462 and 464 may provide overprotection of the loops.

Optionally, a fifth temperature transmitter 466 may be used to monitor the ambient temperature and to adjust fan speed to improve TEG power output when an air-cooled condenser is used.

TEG systems described herein may be modular in that they may include one or more TEG apparatuses as described herein, and each apparatus may be removable and/or replaceable. Each apparatus may include one or more hot plates, one or more cold plates, and one or more TEG elements positioned between each adjacent pair of hot and cold plates. Two or more apparatuses may be connected to the heating and cooling loops. For example, the heating loop may be coupled in parallel to the hot plates of the two or more TEG apparatuses, and the cooling loop may be coupled in parallel to the cold plates of the two or more apparatuses, as will be described below.

FIG. 5 is a side cross-sectional view of a TEG apparatus 500 according to some embodiments. The TEG apparatuses (102,202,302,402) of FIGS. 1 to 4 may include one or more TEG apparatus 500 shown in FIG. 5 although embodiments are not limited to the apparatus configuration shown in FIG. 5.

The TEG apparatus 500 in this example includes a plurality of hot plates 502, a plurality of cold plates 504, and a plurality of TEG element layer 506. Each TEG element layer 506 comprises one or more TEG elements (e.g. TEG modules). The hot plates 502 and cold plates 504 are arranged with front and rear faces aligned substantially vertically and parallel, and the plates (502,504) are stacked in an interleaved, alternating fashion. Each TEG element layer 506 is interposed or sandwiched between a respective pair of adjacent hot plate 502 and cold plate 504. Each TEG element of a TEG element layer 506 may extend between front and back faces of the respective layer 506 for abutting contact with the corresponding hot and cold plates 502 and 504. The TEG element layers 506 may further include insulation filling gaps between the TEG elements of the layer (such as the insulation 912 shown in FIG. 9). The three vertical rows of TEG elements 506 shown between each hot plate 502 and cold plate 504 in FIG. 5 is for illustrative purposes and may be one or more rows.

The TEG apparatus 500 further includes first and second end plates 514a and 514b. The hot and cold plates 502 and 504 and the TEG element layers 506 may be stacked between the end plates 514a and 514b. Rods 516 may extend through the end plates 514a and 514b. Securing hardware 517 and compression elements such as springs 518 mounted over ends of the rods 516 to plates (502,504,514a,514b) and the TEG element layers 506 may provide compressive force. This compressive force may help ensure good contact for heat transfer between the hot/cold plates (502,504) the TEG element layers 506.

The TEG apparatus 500 may further include insulation around sides, top and/or bottom of the apparatus 500. For example, bottom insulation layer 510 is shown in FIG. 5. Any suitable means and material(s) for insulating the apparatus 500 may be used. The insulation layer 510 may comprise, for example, a high compression insulation material. Other insulation examples include, but are not limited to, Pryrogel XTE covered with high temp fabric or high temp paint.

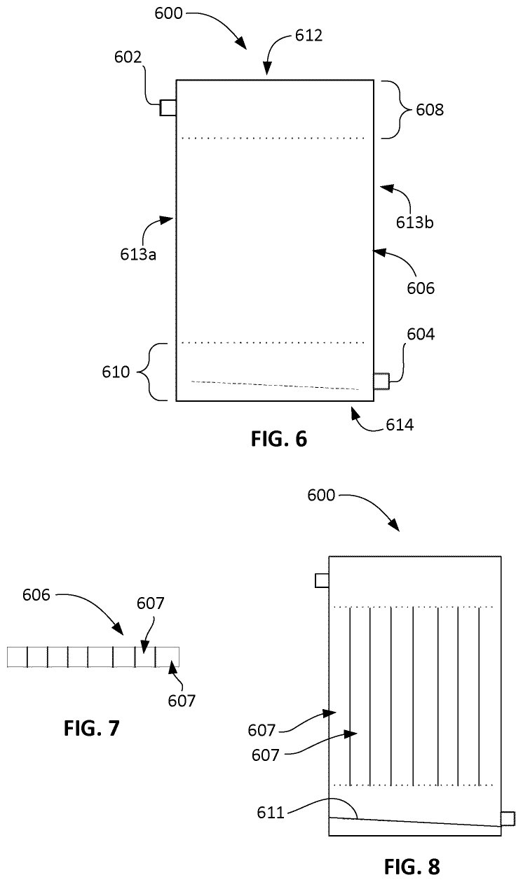

FIG. 6 is a front view of an example plate 600 for a TEG apparatus according to some embodiments. The plate 600 may be used as a hot plate or cold plate. The hot plates 502 and cold plates 504 in FIG. 5 may have the form of the plate 600 in FIG. 6, for example. The plate 600 includes a vapor connection 602 which is an inlet for a hot plate or an outlet for a cold plate; a liquid connection 604 which is an outlet for a hot plate or an inlet for a cold plate; and defines one or more fluid passageways therebetween. More specifically, the plate 600 in this example may comprise a plate body portion 606, a top plate portion 608 above the plate body portion 606, and a bottom plate portion 610 below the plate body portion 606. The plate body portion 606 may define a plurality of fluid channels 607 therethrough from the top plate portion 608 to the bottom plate portion 610.

The top plate portion 608 comprises the vapor connection 602 and the bottom plate portion 610 comprises the liquid connection 604. In this example, the vapor connection 602 is positioned on a first side 613a of the plate 600 and near a top of 612 of the plate 600, while the liquid connection 604 is positioned on a second side 613b near a bottom 614 of the plate 600. However, the positions of the vapor connection 602 and the liquid connection 604 may vary. For example, the vapor connection 602 may be located along the top 612 of the plate 600, while the liquid connection 604 may be located along the bottom 614. These relative positions may assist the different thermal fluid phases to flow through the plates (e.g., in a thermosyphon arrangement). However, embodiments are not limited to any particular location of the vapor connection 602 and liquid connection 604.

The interior of the top plate portion 608 may be hollow or otherwise define fluid passageway(s) between the vapor connection 602 and the upper ends of the fluid channels 607 (see FIG. 7) in the plate body portion 606. Similarly, the bottom plate portion 610 comprises the liquid connection 604. The interior of the bottom plate portion 610 is hollow or otherwise defines one or more fluid passageway(s) between the lower ends of the fluid channels 607 in the plate body portion 606 and the liquid connection 604. Hot-side vapor may thereby enter the plate 600 via the vapor connection 602, travel through the plate 600 via the fluid channels 607 in the plate body portion 606 where the vapor expels heat and condenses to liquid state, with condensed liquid then exiting the liquid connection 604. Cold-side liquid may thereby enter the plate 600 via the liquid connection 604, travel through the plate 600 via the fluid channels 607 in the plate body portion 606 where the liquid absorbs heat and boils to vapor state, with vapor then exiting the vapor connection 602.

Dimensions of the plate 600 may vary depending on implementation and operational considerations. By way of example, the plate 600 may have a height of approximately 40 inches, a width of approximately 13 inches, and a thickness of approximately 1.5 inches. However, embodiments are not limited to particular dimensions of the plate 600.

FIGS. 7 and 8 are top and side cross-sectional views, respectively, of the plate 600 of FIG. 6 illustrating one example form of the fluid channels 607. Embodiments are not limited to any particular form of the fluid channels 607. As shown in FIG. 8, the bottom portion 610 may include a sloped floor 611 to encourage fluid to drain from the plate 600.

The plate 600 may be made of any material suitable for conducting heat from the vapor, such as stainless steel or aluminum. The top plate portion 608 and bottom plate portion 610 may be welded (e.g., fusion welded) to the plate body portion 606 or the plate 600 may be made with continuous metal face sheets joined to components between the sheets. Embodiments are not limited to the configuration of the plate 600 shown in FIGS. 6 to 8.

FIG. 9 is a perspective view of another example TEG apparatus 900 according to some embodiments. The TEG apparatus 900 of FIG. 9 is similar to the example of FIG. 5, in that it includes alternating hot plates 902 and cold plates 904, with each of a plurality of TEG element layers 906 interposed between pairs of adjacent hot and cold plates 902 and 904. The plates (902,904) are oriented with front and rear faces aligned substantially vertically and parallel. The hot plates 902 and cold plates 904 may take the form of the hot plates 902 and cold plates 904 shown in FIGS. 6 to 8. Also similar to the example of FIG. 5, the TEG apparatus 900 in FIG. 9 includes end plates 914a and 914b that are connected by rods 916 holding the plates (902,904) and TEG element layers 906 and maintaining a compressive force (via compression springs 918). Embodiments are not limited to any particular number of plates (902,904) or TEG element layers 906. Embodiments are also not limited to use of end plates (914a,914b) and rods 916, or to any particular number thereof. Other structural means for connecting or securing elements of the apparatus together may be used in other embodiments.

Each TEG element layer 906 in this example includes a plurality of TEG elements 910 abutting the adjacent hot and cold plates 902 and 904. The TEG elements 910 are spaced apart from one another, with insulation 912 filling gaps between the TEG elements 910 of the TEG element layer 906.

FIG. 9 also shows a hot-side fluid supply line 920, hot-side fluid return line 922, cold-side fluid supply line 924, and cold-side fluid return line 926. The hot-side fluid supply line 920 delivers hot vapor to vapor inlets of the hot plates 902, and the hot-side fluid-return line 922 receives condensate from the condensate outlets of the hot plates 902. The hot-side thermal fluid flow through hot plates 902 and lines 920,922 may be part of a heating loop. The cold-side fluid supply line 924 delivers liquid coolant to the inlets of the cold plates 904 and the cold-side fluid return line 926 receives coolant vapor from the outlets of the cold plates 904. The cold-side thermal fluid flow through cold plates 904 and lines 924,926 may be part of a cooling loop.

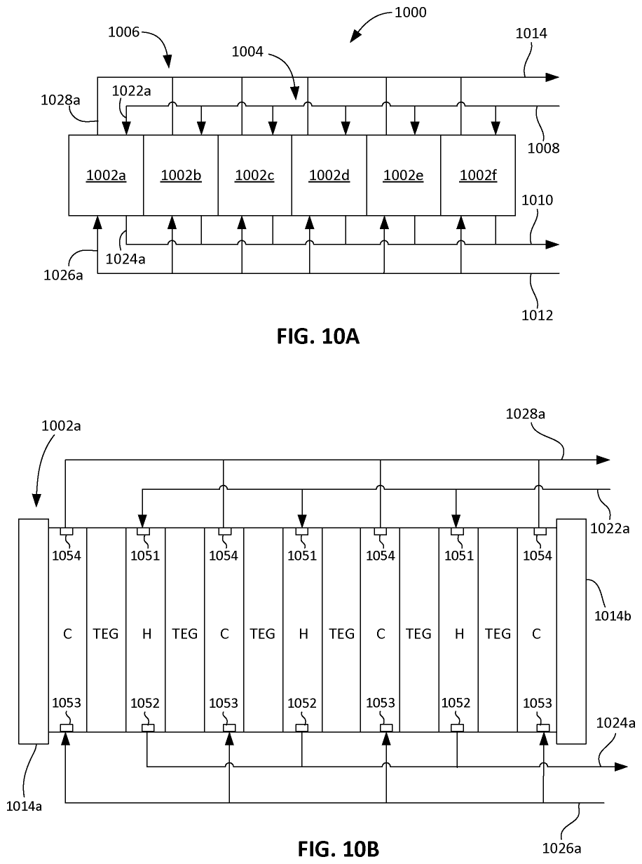

FIG. 10A is a schematic diagram illustrating an example TEG system 1000 comprising a plurality of TEG apparatuses 1002a to 1002f connected in parallel to hot-side fluid lines (1008, 1010); and cold-side thermal fluid lines (1012, 1014). The hot-side thermal fluid system 1004 may be part of a heating loop, such as the examples shown in FIGS. 1 to 4. The cold-side thermal fluid system 1006 may be part of a cooling loop, such as the examples shown in FIGS. 1 to 4. Each of the TEG apparatuses 1002a to 1002f may, for example, take the form of the example TEG apparatuses (500 or 900) shown in FIGS. 5 and 9, although embodiments are not limited to those specific configurations.

As shown, the hot-side thermal fluid system 1004 comprises a hot-side fluid supply line 1008, hot-side fluid return line 1010, and associated hot plates in the TEG apparatuses 1002a to 1002f. The cold-side thermal fluid system 1006 comprises cold-side fluid supply line 1012, cold-side fluid return line 1014, and associated cold plates in the TEG apparatuses 1002a to 1002f. The hot-side fluid supply line 1008 delivers hot vapor in parallel to each of the TEG apparatuses 1002a to 1002f, and the hot-side fluid return line 1010 receives condensate from the TEG apparatuses 1002a to 1002f. The cold-side fluid supply line 1012 delivers liquid coolant in parallel to the TEG apparatuses 1002a to 1002f and the cold-side fluid return line 1014 receives coolant vapor from the TEG apparatuses 1002a to 1002f.

The various thermal fluid lines (1008, 1010, 1012, 1014) may each include branching sub-headers for coupling to the individual TEG apparatuses. For example, for the first TEG apparatus 1002a, the sub-headers may include: a hot-side supply sub-header 1022a connected to the hot-side fluid supply line 1008; a hot-side return sub-header 1024a connected to the hot-side fluid return line 1010; a cold-side supply sub-header 1026a connected to the cold-side fluid supply line 1012; and a cold-side return sub-header 1028a connected to the cold-side fluid return line 1014.

FIG. 10B is a schematic diagram illustrating how the sub-headers (1022a, 1024a, 1026a, 1028a) connect to individual plates of the TEG apparatus 1002a. The apparatus includes a plurality of hot plates “H” and a plurality of cold plates “C”. The plates are arranged in an alternating configuration with each hot plate positioned between a respective pair of cold plates “C”. A TEG layer “TEG” is positioned between an adjacent hot plate “H” and cold plate “C”. End plates 1014a and 1014b are used to secure the plates and TEG layers.

As shown: the hot-side supply sub-header 1022a is coupled in parallel to vapor connections 1051 of hot plates “H”; the hot-side return sub-header 1024a is coupled in parallel to liquid connections 1052 of hot plates “H”: the cold-side supply sub-header 1026a is coupled in parallel to liquid connections 1053 of cold plates “C”; and the cold-side return sub-header 1028a is coupled in parallel to vapor connections 1054 of cold plates “C”.

In the embodiments described herein, the parallel fluid connections to TEG apparatuses and to hot/cold plates within the individual TEG apparatuses may provide for effective flow of heating and coolant thermal fluids through the system, thereby improving electrical generation. The modular design of the system may also allow for easy replacement of individual TEG apparatuses, individual plates and/or TEG elements of the apparatuses. The system may be able to utilize large numbers of plates and TEG elements for large scale electrical energy generation while also facilitating maintenance of the system.

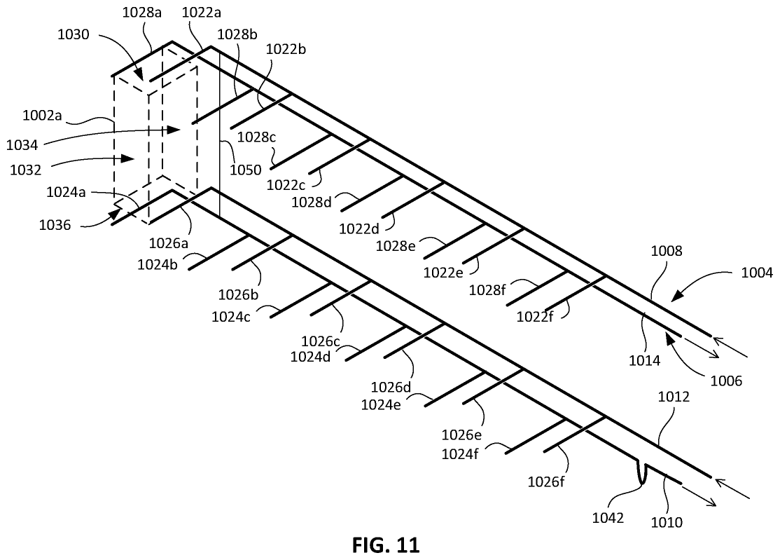

FIG. 11 is perspective view diagram illustrating one possible arrangement of the hot-side thermal fluid system 1004 and cold-side thermal fluid system 1006 of the system 1000 of FIG. 10A. FIG. 11 illustrates a configuration for connecting up to six TEG apparatuses, such as the TEG apparatuses 1002a to 1002f of FIG. 10A. The approximate dimensions of this system may, for example, be approximately 21 feet long by 4 feet tall by 6 feet deep. However, embodiments are not limited to particular dimensions of the system or components thereof. Embodiments are also not limited to a particular number of TEG apparatuses, and a TEG apparatus or system may include more or fewer TEG apparatuses, plates, and elements.

As shown the first TEG apparatus 1002a includes: the hot-side supply sub-header 1022a connected to the hot-side fluid supply line 1008; the hot-side return sub-header 1024a connected to the hot-side fluid return line 1010; the cold-side supply sub-header 1026a connected to the cold-side fluid supply line 1012; and the cold-side return sub-header 1028a connected to the cold-side fluid return line 1014. Six possible apparatus positions are illustrated in FIG. 11, one for each set of sub-headers.

The hot-side supply sub-header 1022a and cold-side return sub-header 1028a form a header extending over a top 1030 of the TEG apparatus 1002a from front to back (relative to front 1032 and back 1034 of the TEG apparatus 1002a shown. The cold-side supply sub-header 1026a and hot-side return sub-header 1024a form a second header extending below a bottom 1036 of the TEG apparatus 1002a. The hot and cold plates of the TEG apparatus 1002a may be stacked along the front-to-back direction such that the sub-headers (1022a, 1024a, 1026a, 1028a) pass over/under each of the plates.

The hot-side thermal fluid system 1004 includes similar hot-side supply sub-headers 1022b to 1022f and hot-side return sub-headers 1024b to 1024f for the remaining TEG apparatuses 1002b to 1002f. The cold-side thermal fluid system 1006 includes similar cold-side supply sub-headers 1026b to 1026f and cold-side return sub-headers 1028b to 1028f for the remaining TEG apparatuses 1002b to 1002f.

The hot-side fluid supply line 1008 and/or hot-side supply sub-headers 1022a to 1022f and the cold-side fluid return line 1014 and/or cold-side return sub-headers 1028a to 1028f may be slightly sloped towards the TEG apparatuses 1002a to 1002f. If any vapor condenses in these lines, the liquid may thereby be urged to flow towards one of the TEG apparatuses 1002a to 1002f to allow for liquid drainage. The hot-side fluid return line 1010 and/or hot-side return sub-headers 1024b to 1024f and the cold-side fluid supply line 1012 and/or cold-side return sub-headers 1026a to 1026f may be slightly sloped away the TEG apparatuses 1002a to 1002f to accommodate draining the lines. Other variations or combinations of the above arrangements to facilitate drainage may also be used.

The hot-side thermal fluid system 1004 includes a pressure equalization line 1050 connected between the hot-side fluid supply line 1008 and the hot-side fluid return line 1010. The pressure equalization line 1050 may equalize pressure between the hot-side supply sub-headers 1022a to 1022f and/or the hot-side return sub-headers 1024a to 1024f and steady the outlet condensate liquid level in a seal leg 1042. The seal leg 1042 may prevent the hot vapor from traveling beyond the liquid seal.

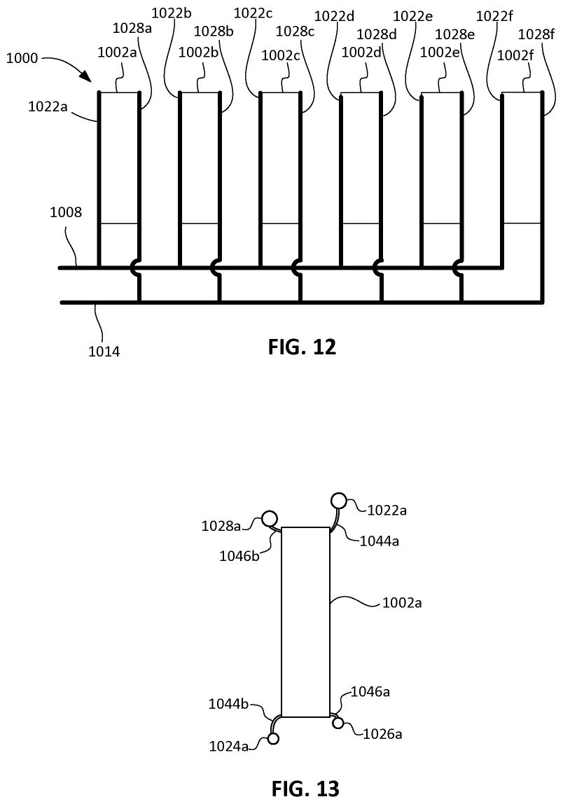

FIG. 12 is a top view diagram of an example the TEG system 1000 including the TEG apparatuses 1002a to 1002f, the hot-side fluid supply line 1008 with hot-side-fluid-in sub-headers 1022a to 1022f, and the cold-side fluid-return line 1014 with cold-side-fluid-return sub-headers 1028a to 1028f. The hot-side fluid-out line 1010 with hot-side-fluid return sub-headers 1024a to 1024f and the cold-side fluid supply line 1014 with cold-side fluid supply sub-headers 1026a to 1026f are not shown in FIG. 12, but will have a similar configuration, but may be positioned under the TEG apparatuses 1002a to 1002f.

As noted above, the number of hot/cold plates and TEG elements in a TEG apparatus may vary. In the examples of FIGS. 10 to 12, for example, each of the TEG apparatuses 1002a to 1002f may include 18 hot plates, 19 cold plates, and 20 TEG elements in each layer between adjacent hot/cold plates. Thus, with six TEG apparatuses, the TEG system may include 4320 TEG elements. In some embodiments, the TEG apparatuses within the system may have different numbers of plates and/or TEG elements.

FIG. 13 is a rear view of the TEG apparatus 1002a of FIG. 12, showing the hot-side supply sub-header 1022a and cold-side return sub-header 1028a above the TEG apparatus, and the cold-side supply sub-header 1026a and hot-side return sub-header 1024a below the TEG apparatus 1002a. A pair of example hot plate inlet and outlet lines 1044a and 1044b connect a front-most hot plate of the TEG apparatus 1002a to the hot-side supply sub-header 1022a and the hot-side return sub-header 1024a, respectively. A pair of cold plate inlet and outlet lines 1446a and 1446b connect a front-most cold plate of the TEG apparatus 1002a to the cold-side supply sub-header 1026a and the cold-side return sub-header 1028a respectively. Each remaining hot and/or cold plate of the TEG apparatus 1002a may be similarly connected to the sub-headers in parallel. In this embodiment, the lines 1444a and 1446b connect inlets/outlets located at the tops of the corresponding hot/cold plates.

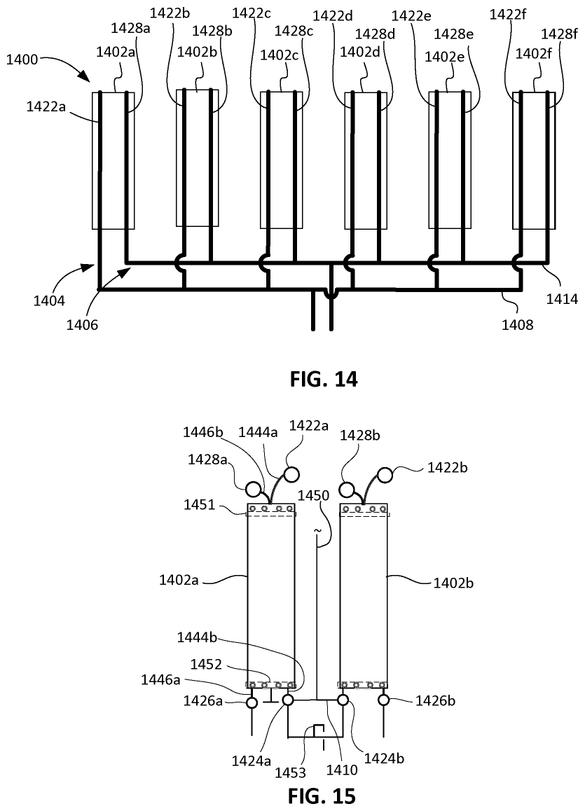

FIG. 14 a top view diagram of another example TEG system 1400 including TEG apparatuses 1402a to 1402f and hot and cold fluid systems 1404 and 1406. Similar to example of FIGS. 11 to 13, the hot-side fluid supply line 1408 with hot-side fluid supply sub-headers 1422a to 1422f, and the cold-side fluid return line 1414 with cold-side fluid return sub-headers 1428a to 1428f. In this embodiment, the sub-headers 1422a to 1422f and 1428a to 1428f are inset somewhat from sides of the TEG apparatuses 1402a to 1402f. The hot-side fluid return line and corresponding sub-headers and the cold-side fluid supply line and corresponding sub-headers are not visible in FIG. 14 but will be positioned under the apparatuses 1402a to 1402f.

FIG. 15 is a front view of two of the TEG apparatuses 1402a and 1402b of FIG. 14. The hot-side supply sub-headers 1422a and 1422b, and the cold-side return sub-headers 1428a and 1428b are again positioned above the corresponding TEG apparatuses. The cold-side supply sub-headers 1426a, 1426b and the hot-side return sub-headers 1424a and 1424b are similarly positioned below the corresponding TEG apparatuses.

A pair of example hot plate inlet and outlet lines 1444a and 1444b connect a front-most hot plate of the TEG apparatus 1402a to the hot-side supply sub-header 1422a and the hot-side return sub-header 1424a, respectively. A pair of cold plate inlet and outlet lines 1446a and 1446b connect a front-most cold plate of the TEG apparatus 1402a to the cold-side supply sub-header 1426a and the cold-side return sub-header 1428a respectively. Each remaining hot and/or cold plate of the TEG apparatus 1402a may be similarly connected to the sub-headers in parallel.

In the embodiment of FIG. 15, the lines 1444a and 1446b connect inlets/outlets located at the tops of the corresponding hot/cold plates, and the lines 1444b and 1446a connect inlets/outlets located at the bottoms of the corresponding hot/cold plates. The embodiment of FIG. 13 shows lines 1044a, 1044b, 1046a and 1046b connected to sides of the plates. Other plate configurations may also have a combination of side and top/bottom connections.

Optional top and bottom insulation 1451 and 1452 are also shown by way of example. However, all hot surfaces including plate sides and piping may be insulated for heat conservation. The insulation 1452 may serve a dual purpose of also providing support for the plates and elements.

FIG. 15 also shows equalization line 1450 and seal leg 1453, which may each be positioned at or near a rear of the apparatuses 1402a and 1402b. The equalization line 1450 may equalize pressure between the hot-side supply line and condensate line and steadies the outlet condensate liquid level. The seal leg 1453 may prevent hot vapor from traveling beyond the seal leg. Each pair of adjacent apparatuses 1402a and 1402b, for example, may have an equalization line 1450 between the hot-side fluid supply line 1408 and cross-connection between the hot-side return sub-headers for each pair of apparatuses. The seal leg 1453 may be installed in a cross-connection between the hot-side return sub-headers 1424a and 1424b. Instead, as shown in FIG. 11 for example, a single equalization line 1040 and seal leg 1042 may be installed in lines 1408 and 1410.

Equipment such as pumps and other equipment may be positioned below the TEG apparatuses. may be located below the TEG apparatuses. For example, the cold-side equipment such as the pump 326, separator 334, condenser 318, and/or treatment apparatus of the system of FIG. 3 may be located below the TEG apparatuses. Hot-side equipment may also be located below the TEG apparatuses. In other embodiments, some equipment may be located above the TEG apparatuses. The TEG apparatuses may be oriented at a single or multiple elevation(s) above both the hot-side and cold-side equipment. All or any part of the equipment and instrumentation, including but not limited to, the TEG apparatuses, power conversion electronics, and computer controls and monitoring may be contained in one or more shipping container and/or skid, and/or other structure.

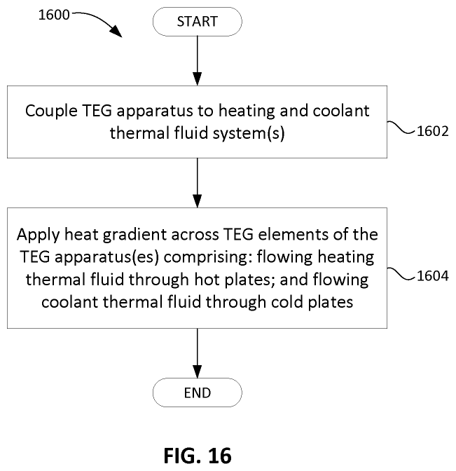

FIG. 16 is a flow chart of a method 1600 for generating electrical energy using the TEG apparatus as described herein. The TEG apparatuses may, for example, take the form of the examples shown in FIGS. 5 or 9 to 15. However, embodiments are not limited to these specific example embodiments. At block 1602, optionally, the TEG apparatus is coupled to heating and coolant thermal fluid system(s). The thermal fluid systems may comprise a heating loop and a cooling loop as described herein. For example, TEG apparatus may be arranged to receive a heating thermal fluid through hot plates of the TEG apparatus and to receive a coolant thermal fluid through cold plates of the TEG apparatus.

At block 1604, a heat gradient is applied across the TEG elements of the TEG layer. Applying the heating gradient comprises: flowing the heating thermal fluid through hot plates of the TEG apparatus; and flowing the coolant thermal fluid through cold plates of the TEG apparatus. Flowing the heating thermal fluid may comprise circulating the heating thermal fluid in a first closed two-phase heat transfer loop comprising a heating thermal fluid supply line and a heating thermal fluid return line. Flowing the coolant thermal fluid may comprise circulating the coolant thermal fluid in a second closed two-phase heat transfer loop comprising a coolant thermal fluid supply line and a coolant thermal fluid return line.

In some embodiments, the heating thermal fluid and the coolant thermal fluid may be the same thermal fluid in a single continuous loop, rather than separate heating and cooling loops. The single thermal fluid may be heated by heat from a heat source, thereby functioning as the heating thermal fluid that is delivered to the hot plates of the TEG apparatus(es). The thermal fluid exiting the hot plates of the TEG apparatus(es) may be cooled by a cold-side heat exchanger and then be delivered to the cold plates, thereby also functioning as the coolant thermal fluid. The thermal fluid exiting the cold plates may be cycled back to the hot-side heat exchanger to be re-heated.

In the embodiments described herein and with reference to FIGS. 1 to 5, the tubing and/or piping used for the hot-side and cold-side loops may comprise stainless steel, for example. The tubing and/or piping material may be suitable for the high temperature and pressure and chemical effects of the fluid contained within. The fluid in the hot-side loop may, for example, may operate at 240° C. and 465 psig with steam and the fluid in the cold-side loop may operate at 35° C. and 181 psig with ammonia, although embodiments are not limited to a particular temperature, pressure, or thermal fluid.

Embodiments of this disclosure are not limited to two-phase thermal fluid loops or closed thermal fluid loops. For example, in the embodiments of FIGS. 5 to 15, a heat source and/or cooling source may be directly applied to either or both the hot-plates and/or cold-plates of the apparatuses without the need for a closed heating loop and/or closing loop. This may be done where the thermal fluid, such as saturated steam for a heating fluid, is clean (also described as non-fouling) and is compatible with the operating conditions and material of the plates. Embodiments may also utilize single-phase thermal fluid(s) systems to apply heat to the hot plates and transfer heat away from cold plates.

It is to be understood that a combination of more than one of the approaches or embodiments described above may be implemented. Embodiments are not limited to any particular one or more of the approaches, methods or apparatuses disclosed herein. One skilled in the art will appreciate that variations or alterations of the embodiments described herein may be made in various implementations without departing from the scope of the claims.

1. A thermoelectric generator (TEG) apparatus comprising:
a plurality of hot-side heat exchange plates for receiving a heating thermal fluid;
a plurality of cold-side heat exchange plates for receiving a coolant thermal fluid, the cold-side heat exchange plates and hot-side heat exchange plates being interleaved such that each hot-side heat exchange plate is positioned intermediate a respective pair of cold-side heat exchange plates; and
for each adjacent hot-side heat exchange plate and cold-side heat exchange plate, a respective TEG element layer interposed between the hot-side heat exchange plate and the cold-side heat exchange plate.

2. The TEG apparatus of claim 1, wherein the TEG layer comprises a plurality of TEG elements, each TEG module comprising a hot side and a cold side and configured for thermoelectric generation of electricity when a heat gradient is applied across the TEG element, wherein the hot sides of the TEG elements are positioned adjacent the hot-side heat exchange plates, and the cold sides of the TEG elements are positioned adjacent the cold-side heat exchange plates.

3. The TEG apparatus of claim 2, further comprising, for each TEG element layer, an insulating material at least partially filling gaps between the TEG elements of the TEG element layer.

4. The TEG apparatus of claim 1, wherein: the hot-side heat exchange plates form a condenser for receiving the heating thermal fluid as a first vapor and condensing the thermal fluid to a first liquid; and the cold-side heat exchange plates form an evaporator for receiving the coolant thermal fluid as a second liquid and evaporating the thermal fluid to a second vapor.

5. The TEG apparatus of claim 1, wherein the hot-side heat exchange plates each comprise a respective heating thermal fluid inlet and heating thermal fluid outlet, the cold-side heat exchange plates each comprise a respective coolant thermal fluid inlet and coolant thermal fluid outlet.,

6. The TEG apparatus of claim 5, further comprising:
a heating thermal fluid supply line coupled in parallel to heating thermal fluid inlets of the hot-side heat exchange plates;
a heating thermal fluid return line coupled in parallel to the heating thermal fluid outlets the hot-side heat exchange plates;
a coolant thermal fluid supply line coupled in parallel to coolant thermal fluid inlets of the cold-side heat exchange plates; and
a coolant thermal fluid return line coupled in parallel to coolant thermal fluid outlets of the cold-side heat exchange plates.

7. The TEG apparatus of claim 6, further comprising a pressure equalization line connected between the heating thermal fluid supply line and the heating thermal fluid return line.

8. The TEG apparatus of claim 6, further comprising first and second end plates, wherein the hot-side heat exchange plates, the cold-side heat exchange plates, and the TEG element layers are secured between the first and second end plates.

9. The TEG apparatus of claim 8, further comprising one or more biasing elements to apply a compressive force to the first and second end plates, hot-side heat exchange plates, the cold-side heat exchange plates, and the TEG element layers.

10. A thermoelectric generator (TEG) system, comprising:
one or more TEG apparatuses, each comprising:
a respective plurality of hot-side heat exchange plates for receiving a heating thermal fluid;
a respective plurality of cold-side heat exchange plates for receiving a coolant thermal fluid, the cold-side heat exchange plates and hot-side heat exchange plates being interleaved such that each hot-side heat exchange plate is positioned intermediate a respective pair of cold-side heat exchange plates; and
for each adjacent hot-side heat exchange plate and cold-side heat exchange plate, a respective TEG element layer interposed between the hot-side heat exchange plate and the cold-side heat exchange plate;
a heating thermal fluid system, comprising a heating thermal fluid supply line and a heating thermal fluid return line, each coupled to the hot-side heat exchange plates of the one or more TEG apparatuses; and
a coolant thermal fluid system, comprising a coolant thermal fluid supply line and a coolant thermal fluid return line, each coupled to the cold-side heat exchange plates of the one or more TEG apparatuses.

11. The TEG system of claim 10, further comprising a pressure equalization line connected between the heating thermal fluid supply line and the heating thermal fluid return line.

12. The TEG system of claim 11, wherein:
the hot-side heat exchange plates each comprise a respective heating thermal fluid inlet and heating thermal fluid outlet, the cold-side heat exchange plates each comprise a respective coolant thermal fluid inlet and coolant thermal fluid outlet, and
the heating thermal fluid supply line is coupled in parallel to heating thermal fluid inlets of the hot-side heat exchange plates;
the heating thermal fluid return line is coupled in parallel to the heating thermal fluid outlets the hot-side heat exchange plates;
the coolant thermal fluid supply line is coupled in parallel to coolant thermal fluid inlets of the cold-side heat exchange plates; and
the coolant thermal fluid return line is coupled in parallel to coolant thermal fluid outlets of the cold-side heat exchange plates.

13. The TEG system of claim 10, further comprising:
a first closed two-phase heat transfer loop arranged to deliver heat from a heat source to the plurality of hot-side heat exchange plates, first closed two-phase heat transfer loop comprising the heating thermal fluid supply line and the heating thermal fluid return line; and
a second closed two-phase heat transfer loop arranged to transfer heat away from the plurality of cold-side heat exchange plates, the second closed two-phase heat transfer loop comprising the coolant thermal fluid supply line and the coolant thermal fluid return line.

14. The TEG system of claim 13, wherein:
the first closed two-phase heat transfer loop comprises a first thermosyphon for circulating the heating thermal fluid; and/or
the second closed two-phase heat transfer loop comprises a second thermosyphon for circulating the coolant thermal fluid.

15. The TEG system of claim 13, further comprising:
one or more heat exchangers arranged to transfer heat from a heat source to the heating thermal fluid; and
one or more other heat exchangers arranged to remove heat from the coolant thermal fluid.

16. The TEG system of claim 10, the one or more TEG apparatuses comprise a plurality of TEG apparatuses.

17. (canceled)

18. A method for generating electrical energy using the TEG apparatus of claim 1, the method comprising:
applying a heat gradient across the TEG elements of the TEG apparatus, comprising:
flowing the heating thermal fluid through the plurality of hot-side heat exchange plates of the TEG apparatus; and
flowing the coolant thermal fluid through the plurality of cold-side heat exchange plates of the TEG apparatus.

19. The method of claim 18, wherein:
flowing the heating thermal fluid comprises circulating the heating thermal fluid in a first closed two-phase heat transfer loop comprising a heating thermal fluid supply line and a heating thermal fluid return line; and
flowing the coolant thermal fluid comprises circulating the coolant thermal fluid in a second closed two-phase heat transfer loop comprising a coolant thermal fluid supply line and a coolant thermal fluid return line.

20. The method of claim 19, wherein the first closed two-phase heat transfer loop comprises a first thermosyphon for circulating the heating thermal fluid; and/or the second closed two-phase heat transfer loop comprises a second thermosyphon for circulating the coolant thermal fluid.
